(19) United States
(12) Patent Application Publication
(10) Pub. No.: US 2024/0096620 A1
(43) Pub. Date: Mar. 21, 2024

(54) METHOD OF FILLING A TRENCH FORMED IN A SEMICONDUCTOR SUBSTRATE

(71) Applicant: STMicroelectronics (Crolles 2) SAS, Crolles (FR)

(72) Inventor: Bilel Saidi, Grenoble (FR)

(21) Appl. No.: 18/466,542

(22) Filed: Sep. 13, 2023

(30) Foreign Application Priority Data
Sep. 19, 2022 (FR) 2209435

(51) Int. Cl. H01L 21/02; H01L 29/04

(52) U.S. Cl. CPC H01L 21/02667; H01L 21/02532; H01L 21/02592; H01L 21/02595; H01L 29/04

(57) ABSTRACT

An embodiment provides a method of forming a semiconductor device. A first silicon layer is deposited in a trench of a semiconductor substrate as an amorphous layer. A second silicon layer is deposited on top of and in contact with the first silicon layer as a polysilicon layer. After depositing the second silicon layer, the first silicon layer includes polysilicon having an average grain size different than an average grain size of the second silicon layer. A third semiconductor layer is deposited on top of and in contact with the second silicon layer to at least partially fill the trench.

### CROSS-REFERENCE TO RELATED APPLICATIONS

This application claims the benefit of French Application No. 2209435, filed on Sep. 19, 2022, which application is hereby incorporated herein by reference.

### TECHNICAL FIELD

The present disclosure generally concerns the field of semiconductor devices and of their fabrication methods.

### BACKGROUND

Various electronic devices comprising trenches extending vertically in a semiconductor substrate and partially or totally filled with polysilicon have been provided.

Such trenches are for example used to form insulating walls laterally separating different elements of an integrated circuit, for example, different pixels of an image sensor or different elementary storage cells of a memory circuit, or also to form vertical electronic components such as vertical transistors or vertical capacitors.

A difficulty is that the filling of the trenches with polysilicon can induce strong mechanical stress on the substrate, likely to raise issues during the manufacturing of the devices.

It would be desirable to overcome all or part of the disadvantages of known methods of filling, with polysilicon, a trench formed in a semiconductor substrate.

### SUMMARY

An embodiment provides a method of filling a trench formed in a semiconductor substrate. This embodiment can include the steps: a) depositing a first silicon layer in amorphous deposition conditions on the lateral walls and at the bottom of the trench; b) depositing a second silicon layer in polycrystalline deposition conditions on top of and in contact with the first layer; and c) depositing a third doped silicon layer in amorphous deposition conditions on top of and in contact with the second layer to entirely fill the trench. At the end of step b), the first layer is made of polysilicon having a grain size different than that of the second layer.

According to an embodiment, the silicon of the first layer crystallizes and transits from an amorphous state to a polycrystalline state during the deposition of the second layer under the effect of the conditions of deposition of the second layer.

According to an embodiment, the method comprises between step a) and step b), an intermediate anneal step during which the silicon of the first layer crystallizes and transits from an amorphous state to a polycrystalline state.

According to an embodiment, at the end of step c), the first silicon layer is tensile and the second silicon layer is compressive.

According to an embodiment, the second silicon layer is deposited in situ in the same deposition chamber as the first silicon layer, without extracting the substrate from the chamber between the two depositions.

According to an embodiment, the method comprises, before step a), a step of deposition of a dielectric layer on the lateral walls and at the bottom of the trench.

According to an embodiment, at step a), the first silicon layer is deposited on top of and in contact with the dielectric layer.

According to an embodiment, the first silicon layer is doped in situ during its deposition.

According to an embodiment, the method comprises a step of thinning of the substrate from its surface opposite to the trench between step b) and step c).

According to an embodiment, the method comprises a step of rapid thermal anneal between the thinning step and step c).

Another embodiment provides an electronic device comprising a trench arranged in a semiconductor substrate. A first polysilicon layer coats the lateral walls and the bottom of the trench and a second polysilicon layer is located on top of and in contact with the first layer. A third doped silicon layer is located on top of and in contact with the second layer. The third layer completes the total filling of the trench. The polysilicon of the first layer has a grain size different from that of the polysilicon of the second layer.

According to an embodiment, the polysilicon of the first layer has an average grain size in the range from 50 to 120 nm, and the polysilicon of the second layer has an average grain size in the range from 10 to 30 nm.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A is a cross-section view of a semiconductor structure illustrating a step of an example of a method of filling a trench according to an embodiment;

FIG. 1B is a cross-section view of a semiconductor structure illustrating a step of an example of a method of filling a trench according to an embodiment;

FIG. 1C is a cross-section view of a semiconductor structure illustrating a step of an example of a method of filling a trench according to an embodiment;

FIG. 1D is a cross-section view of a semiconductor structure illustrating a step of an example of a method of filling a trench according to an embodiment;

FIG. 1E is a cross-section view of a semiconductor structure illustrating a step of an example of a method of filling a trench according to an embodiment;

FIG. 1F is a cross-section view of a semiconductor structure illustrating a step of an example of a method of filling a trench according to an embodiment;

FIG. 2A is a cross-section view of a semiconductor structure illustrating a step of an example of a method of filling a trench according to an embodiment; and

FIG. 2B is a cross-section view of a semiconductor structure illustrating a step of an example of a method of filling a trench according to an embodiment

### DETAILED DESCRIPTION OF EMBODIMENTS

Like features have been designated by like references in the various figures. In particular, the structural and/or functional features that are common among the various embodiments may have the same references.

For the sake of clarity, only the steps and elements that are useful for an understanding of the embodiments described herein have been illustrated and described in detail. In particular, only the forming of the trenches of the electronic devices has been detailed. The other elements of the electronic devices have not been detailed, the described embodiments being compatible with all or most known embodiments of electronic devices comprising trenches filled with polysilicon.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

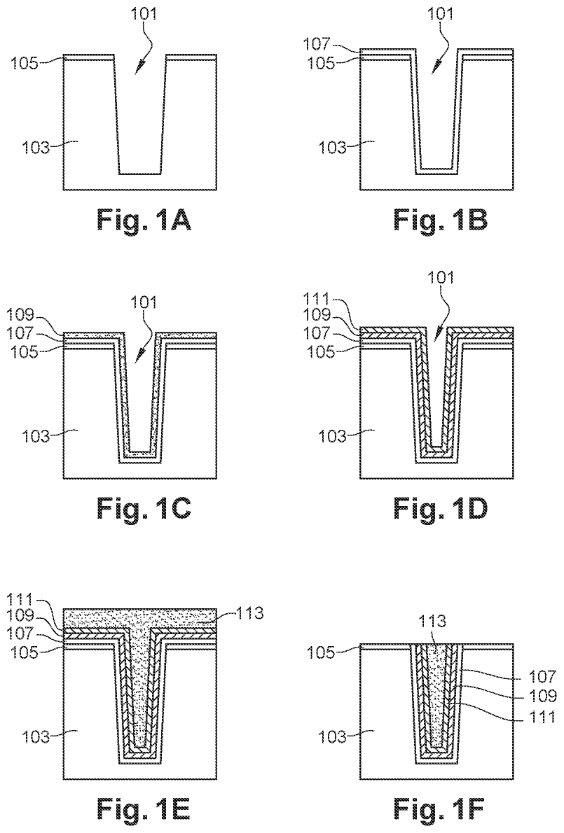

FIGS. 1A to 1F are partial and simplified cross-section views illustrating successive steps of an example of a trench filling method according to an embodiment.

FIG. 1A illustrates a structure obtained at the end of a step of forming of a trench 101 in a semiconductor substrate 103. The trench can extend vertically from a surface of the substrate, the upper surface in the shown example, down to a depth smaller than the thickness of substrate 103, for example down to a depth in the range from 1 to 50 μm, or for example from 2 to 15 μm, or for example, in the order of 6 μm.

The width of trench 101 can be for example in the range from 0.1 to 2 m, or for example, in the order of 600 nm.

Substrate 103 can be for example made of silicon, for example, of single-crystal silicon. The described embodiments are however not necessarily limited to this specific case and can apply to substrates made of other semiconductor materials, comprising or not silicon.

In the shown example, the upper surface of the substrate can be coated with a dielectric passivation layer 105, for example, made of silicon nitride. Trench 103 can extend through layer 105.

Trench 101 can be for example formed by photolithography and then etching, for example by a plasma etching method, or for example, by a method of DRIE (“Deep Reactive Ion Etching”) type.

FIG. 1B illustrates a structure obtained at the end of an optional step of deposition of a layer or liner 107 of a dielectric material, for example, silicon oxide, on the lateral walls and on the bottom of trench 101. In this example, layer 107 can be used to electrically insulate the semiconductor material of the substrate from the polysilicon subsequently deposited in the trench. In this example, layer 107 can be in contact with the material of substrate 103 on the lateral walls and on the bottom of trench 101. Layer 107 can be for example deposited by a conformal deposition method over the entire upper surface of substrate 103. Thus, in the shown example, layer 107 can further extend on the upper surface of dielectric layer 105. The thickness of dielectric layer 107 can be for example in the range from 2 nm to 200 nm.

FIG. 1C illustrates a structure obtained at the end of a step of deposition of an amorphous silicon layer 109 on the lateral walls and on the bottom of trench 101. In this example, layer 109 can be deposited on top of and in contact with the upper surface of dielectric layer 107. Layer 109 can be for example deposited by a method of conformal deposition over the entire upper surface of substrate 103. The thickness of amorphous silicon layer 109 can be for example in the range from 50 to 500 nm, or for example, in the order of 150 nm.

Preferably, layer 109 can be doped in situ during its deposition. The doping can be of type P or of type N. As an example, the doping can be a boron or phosphorus doping. The doping level of layer 109 can be for example in the range from 1×1018 atoms/cm3 to 1×1022 atoms/cm3.

The deposition can be for example performed at a temperature lower than 600° C., or for example, in the range from 400 to 580° C., to obtain an amorphous state of the silicon of layer 109 at the end of the deposition.

FIG. 1D illustrates a structure obtained at the end of a step of in situ deposition of a polysilicon layer 111 on the lateral walls and on the bottom of trench 101 after the deposition of layer 109. In this example, layer 111 can be deposited on top of and in contact with the upper surface of amorphous silicon layer 109. Layer 111 can be for example deposited by a conformal deposition method over the entire upper surface of substrate 103. The thickness of polysilicon layer 111 can be for example in the range from 50 to 500 nm, or for example, in the order of 130 nm.

Layer 111 can be for example non-doped (e.g., non-intentionally doped). As a variant, layer 111 can be doped in situ during its deposition. The doping can then be of type P or of type N. As an example, the doping can be a boron or phosphorus doping. The doping level of layer in can be for example in the range from 1×1018 atoms/cm3 to 1×1022 atoms/cm3.

The deposition can be for example performed at a temperature higher than 580° C., or for example, in the range from 600 to 700° C., to obtain a polycrystalline state of the deposited silicon.

By in situ deposition, here it is meant that layer 111 can be deposited in the same deposition chamber as that used to perform the deposition of layer 109 at the step of FIG. 1C, without taking the structure out of the chamber between the deposition of layer 109 and the deposition of layer in.

In this example, no intermediate anneal is provided between the deposition of layer 109 and the deposition of layer in, so that the silicon of layer 109 can be still amorphous at the beginning of the step of deposition of layer in.

The temperature in the chamber during the deposition of layer 111 can induce an in situ recrystallization of amorphous silicon layer 109. Thus, during the deposition of polysilicon layer 111, amorphous silicon layer 109 can be transformed into polysilicon.

The polysilicon of layer 109, obtained by in situ recrystallization of the amorphous silicon deposited at the previous step, can be tensile, that is, it can exert a tensile force (stretching) on the material of substrate 103, parallel to the plane of layer 109. The polysilicon of layer 111, obtained directly by deposition in polycrystalline deposition conditions, can be compressive, that is, it can exert a compressive force on the material of substrate 103, parallel to the plane of layer 111. Thus, the tensile force exerted by layer 109 can be at least partially compensated for by the compressive force exerted by layer 111, which can enable limiting or reducing deformations of substrate 103 previously linked to the filling of trenches 101. As an example, the polysilicon layer of layer 109 can exert a tensile force in the range from 100 to 500 MPa, and the polysilicon of layer 111 can exert a compressive force in the range from 100 to 500 MPa. It should be noted that these values can depend on the applied thermal budgets, on the dopant chemical elements, and on the doping levels, as well as on the deposited thicknesses. Further, the impact on the deformation of the plates can be variable according to the density of the trenches per wafer and the depth thereof.

It should be noted that, in practice, at the end of the method, due to their different forming conditions (amorphous deposition and recrystallization into polysilicon for layer 109 and polycrystalline deposition for layer 111), polysilicon layers 109 and 11 can have different grain sizes. As an example, layer 109 can have an average grain size greater than that of layer 111. As an example, the polysilicon of layer 111 can have an average grain size varying from 10 to 30 nm, for example, with a columnar growth. The recrystallized amorphous silicon of layer 109 for example can have an average grain size varying from 50 to 120 nm, for example, with a random grain distribution. These grain sizes and arrangements can fluctuate according to the thermal budgets, to the dopant chemical element, as well as to the concentration thereof, to the deposition surface, etc.

FIG. 1E illustrates a structure obtained at the end of a step of filling of trench 101 with a doped amorphous silicon layer 113. Layer 113 can be deposited on top of and in contact with the upper surface of polysilicon layer 111, for example. Layer 113 can be for example deposited over the entire upper surface of substrate 103. The thickness of amorphous silicon layer 113 can be selected to be sufficiently high to complete the total filling of trench 101.

Preferably, layer 113 can be doped in situ during its deposition. The doping can be of type P or of type N. As an example, the doping can be a boron or phosphorus doping. The doping level of layer 113 can be for example in the range from 1×1018 atoms/cm3 to 1×1022 atoms/cm3.

The deposition of layer 113 can be for example performed at a temperature lower than 600° C., or for example, in the range from 400 to 580° C., to obtain an amorphous state of the silicon of layer 113 at the end of the deposition.

FIG. 1F illustrates a structure obtained at the end of a step of planarization of its upper surface, for example by chemical-mechanical polishing. During this step, the structure can be thinned from its upper surface to remove the portions of layers 113, 111, 109, and 107 coating the upper surface of substrate 103, to expose the upper surface of dielectric passivation layer 105. The thinning can be for example interrupted on the upper surface of dielectric passivation layer 105.

An advantage of the method described in relation with FIGS. 1A to 1F can be that it enables to perform a filling of trenches formed in a substrate, while limiting the deformations of the substrate under the effect of the stress exerted by the trench filling material.

This can be particularly advantageous when the density of the trenches at the surface of the substrate is significant, for example, greater than 9%, and particularly when the trenches are deep, for example, with a depth greater than 2 m.

After the step of deposition of polysilicon layer 111 and before the deposition of layer 113, a thermal treatment, for example, an anneal of RTP (“Rapid Thermal Processing”) type, can advantageously be implemented, to relax the strain of layers 109 and 11 before the final filling with layer 113. The anneal can be for example implemented at a temperature in the range from 800° C. to 1,200° C., or for example, in the order of 955° C. The duration of the anneal can be for example in the range from 2 seconds to 5 minutes.

In the example described in relation with FIGS. 1A to 1E, the amorphous silicon layer 109 deposited at the step of FIG. 1C can be transformed into polysilicon during the step of deposition of polysilicon layer 111.

As a variant, an intermediate step of in-situ anneal of layer 109, resulting in transforming the amorphous silicon of layer 109 into polysilicon, can be implemented before the deposition of layer 111. By in-situ anneal, it is here meant that the anneal can be implemented in the chamber used to perform the deposition at the step of FIG. 1C, without taking the structure out of the chamber between the deposition and the anneal. The anneal can be for example implemented at a temperature higher than 560° C., or for example, in the range from 580° C. to 900° C.

The in-situ anneal of amorphous silicon layer 109 here again can result in transforming layer 109 into a tensile polysilicon layer, that is, exerting a tensile force (stretching) on the material of substrate 103, parallel to the plane of layer 109.

Polysilicon layer 111 can then be deposited in situ (in the same equipment) on polysilicon layer 109, with the rest of the method being identical to what has been previously described, for example as another embodiment.

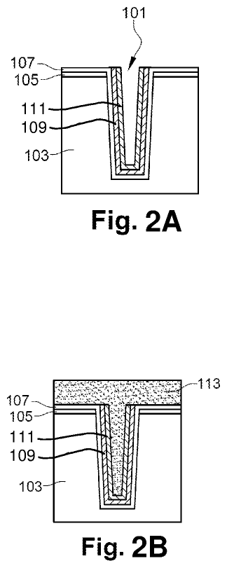

As shown in FIGS. 2A and 2B, as a variant, between the depositing of layer 111 and the depositing of layer 113, an upper surface of an intermediate structure shown in FIG. 1D can be thinned, by removing portions of layer 111, or removing portions of layer 111 and layer 109 as illustrated in FIG. 2B, or removing portions of layer 111, layer 109, and layer 107.

The trenches formed by the above-described methods for example can form insulating walls laterally separating different elements of an integrated circuit; for example, different pixels of an image sensor or different elementary storage cells of a memory circuit. As a variant, these trenches can form vertical electronic components such as vertical transistors or vertical capacitors.

Various embodiments and variants have been described. Those skilled in the art can understand that certain features of these various embodiments and variants can be combined, and other variants can occur to those skilled in the art. In particular, the described embodiments are not necessarily limited to the above-mentioned examples of application.

Finally, the practical implementation of the described embodiments and variations is within the abilities of those skilled in the art based on the functional indications given hereabove.

What is claimed is:

1. A method of forming a semiconductor device, the method comprising:
depositing a first silicon layer in a trench of a semiconductor substrate, the first silicon layer being deposited as an amorphous layer;
depositing a second silicon layer on top of and in contact with the first silicon layer, the second silicon layer being deposited as a polysilicon layer, wherein, after depositing the second silicon layer, the first silicon layer comprises polysilicon having an average grain size different than an average grain size of the second silicon layer; and
depositing a third semiconductor layer on top of and in contact with the second silicon layer to fill the trench.

2. The method of claim 1, wherein silicon of the first silicon layer crystallizes and transition from an amorphous state to a polycrystalline state during the depositing of the second silicon layer, under effect of the conditions of depositing of the second silicon layer.

3. The method of claim 1, further comprising, after depositing of the first silicon layer and before depositing the second silicon layer, annealing the first silicon layer to crystallize and transition the first silicon layer from an amorphous state to a polycrystalline state.

4. The method of claim 1, wherein, after depositing the third semiconductor layer, the first silicon layer is tensile and the second silicon layer is compressive.

5. The method of claim 1, wherein depositing the first silicon layer and depositing the second silicon layer comprises depositing the first silicon layer and depositing the second silicon layer in situ in the same deposition chamber without removing the substrate from the chamber between depositing the first silicon layer and depositing the second silicon layer.

6. The method of claim 1, further comprising depositing a dielectric layer in the trench before the depositing of the first silicon layer.

7. The method of claim 6, wherein depositing the first silicon layer comprises depositing the first silicon layer on top of and in contact with the dielectric layer.

8. The method of claim 1, wherein the first silicon layer is doped in situ when depositing the first silicon layer.

9. The method of claim 1, further comprising, after depositing the second silicon layer and before depositing the third semiconductor layer, thinning an intermediate structure formed after the depositing of the second silicon layer by removing portions of an upper surface of the intermediate structure.

10. The method of claim 9, further comprising performing a rapid thermal anneal after thinning the intermediate structure and before depositing the third semiconductor layer.

11. The method of claim 1, wherein the third semiconductor layer comprises a third doped silicon layer, and wherein depositing the third semiconductor layer comprises depositing the third doped silicon layer in amorphous deposition conditions.

12. The method of claim 1, wherein the first silicon layer comprises polysilicon having an average grain size larger than the grain size of the second silicon layer.

13. The method of claim 12, wherein the average grain size of the first silicon layer is in the range from 50 to 120 nm, and the average grain size of the second silicon layer is in the range from 10 to 30 nm.

14. An semiconductor device comprising:
a semiconductor substrate with a trench disposed therein;
a dielectric layer contacting lateral walls and a bottom of the trench;
a first polysilicon layer over and in contact with the dielectric layer;
a second polysilicon layer over and in contact with the first polysilicon layer, wherein the second polysilicon layer has an average grain size different than an average grain size of the second polysilicon layer; and
a third doped silicon layer over and in contact with the second polysilicon layer, the third doped silicon layer completely filling the trench.

15. The device of claim 14, wherein the average grain size of the first polysilicon layer is in the range from 50 to 120 nm, and the average grain size of the second polysilicon layer is in the range from 10 to 30 nm.

16. The device of claim 14, wherein the first polysilicon layer is tensile and the second polysilicon layer is compressive.

17. A method of forming a semiconductor device, the method comprising:
depositing a dielectric layer on lateral walls and at a bottom of a trench of a semiconductor substrate;
depositing a first silicon layer over the dielectric layer, the first silicon layer being deposited in amorphous deposition conditions as an amorphous layer;
depositing a second silicon layer in contact with the first silicon layer, the second silicon layer being deposited in polysilicon deposition conditions as a polysilicon layer, wherein silicon of the first silicon layer crystallizes and transition from an amorphous state to a polycrystalline state when depositing the second silicon layer so that the first silicon layer comprises polysilicon having an average grain size different than an average grain size of the second silicon layer; and
depositing a third semiconductor layer in contact with the second silicon layer to fill the trench, the third semiconductor layer being deposited in amorphous deposition conditions.

18. The method of claim 17, wherein, after depositing the third semiconductor layer, the first silicon layer is tensile and the second silicon layer is compressive.

19. The method of claim 17, wherein depositing the first silicon layer and depositing the second silicon layer comprises depositing the first silicon layer and then depositing the second silicon layer in the same deposition chamber without removing the substrate from the chamber between depositing the first silicon layer and depositing the second silicon layer.

20. The method of claim 17, further comprising, after depositing the second silicon layer and before depositing the third semiconductor layer, thinning an intermediate structure formed after the depositing of the second silicon layer by removing portions of an upper surface of the intermediate structure.

21. The method of claim 17, wherein the average grain size of the first silicon layer is in the range from 50 to 120 nm, and the average grain size of the second silicon layer is in the range from 10 to 30 nm.

22. A method of forming a semiconductor device, the method comprising:
depositing a dielectric layer on lateral walls and at a bottom of a trench of a semiconductor substrate;
depositing a first silicon layer over the dielectric layer, the first silicon layer being deposited in amorphous deposition conditions as an amorphous layer;
after depositing of the first silicon layer, annealing the first silicon layer to crystallize and transition the first silicon layer from an amorphous state to a polycrystalline state;
after annealing the first silicon layer, depositing a second silicon layer in contact with the first silicon layer, the second silicon layer being deposited in polysilicon deposition conditions as a polysilicon layer, wherein the second silicon layer comprises polysilicon having an average grain size different than an average grain size of the first silicon layer; and
depositing a third semiconductor layer in contact with the second silicon layer to at least partially fill the trench, the third semiconductor layer being deposited in amorphous deposition conditions.

23. The method of claim 22, wherein, after depositing the third semiconductor layer, the first silicon layer is tensile and the second silicon layer is compressive.

24. The method of claim 22, further comprising, after depositing the second silicon layer and before depositing the third semiconductor layer, thinning an intermediate structure formed after the depositing of the second silicon layer by removing portions of an upper surface of the intermediate structure.

25. The method of claim 22, wherein the average grain size of the first silicon layer is in the range from 50 to 120 nm, and the average grain size of the second silicon layer is in the range from 10 to 30 nm.
